(19) United States
(12) Patent Application Publication
(10) Pub. No.: US 2025/0019588 A1
(43) Pub. Date: Jan. 16, 2025

(54) CURABLE COMPOSITION, CURED LAYER PREPARED USING THE COMPOSITION, COLOR FILTER INCLUDING THE CURED LAYER, AND DISPLAY DEVICE INCLUDING THE COLOR FILTER

(71) Applicant: SAMSUNG SDI CO., LTD., Yongin-si, Gyeonggi-do (KR)

(72) Inventors: Jonggi KIM, Suwon-si (KR); Kyunghee KANG, Suwon-si (KR); Yonghee KANG, Suwon-si (KR); Bumjin LEE, Suwon-si (KR); Jihyeon YIM, Suwon-si (KR); Hyunsook JANG, Suwon-si (KR)

(21) Appl. No.: 18/696,956

(22) PCT Filed: Sep. 6, 2022
(86) PCT No.: PCT/KR2022/013296

§ 371 Date: Sep. 26, 2024

(30) Foreign Application Priority Data
Sep. 30, 2021 (KR) 10-2021-0129534

(51) Int. Cl. C09K 11/02; C08F 2/44; C09K 11/06; G02F 1/1335; G03F 7/00; G03F 7/028

(52) U.S. Cl. CPC C09K 11/02; C08F 2/44; C09K 11/06; G02F 1/133514; G03F 7/0007; G03F 7/028

(57) ABSTRACT

Provided are a curable composition including (A) a quantum dot surface-modified with at least two surface-modifying materials; and (B) a polymerizable compound, wherein the surface-modifying material includes a first surface-modifying material and a second surface-modifying material, a cured layer manufactured using the curable composition, a color filter including the cured layer, and a display device including the color filter.

### TECHNICAL FIELD

The present disclosure relates to a curable composition, a cured layer manufactured using the composition, a color filter including the cured layer, and a display device including the color filter.

### BACKGROUND ART

In the case of general quantum dots, due to surface characteristics having hydrophobicity, a solvent in which it is dispersed is limited, and thus, it is difficult to introduce into a polar system such as a binder or a curable monomer.

For example, even in the case of a quantum dot ink composition being actively researched, a polarity is relatively low in an initial step and it may be dispersed in a solvent used in a curable composition having a high hydrophobicity. Therefore, because 20 wt % or more of quantum dots are difficult to be included based on the total amount of the composition, it is impossible to increase light efficiency of the ink over a certain level. Even though the quantum dots are additionally added and dispersed in order to increase light efficiency, a viscosity exceeds a range capable of ink-jetting and thus processability may not be satisfied.

In order to achieve the viscosity range capable of ink-jetting, a method of lowering an ink solid content by dissolving 50 wt % or more of a solvent based on the total amount of the composition, which also provides a somewhat satisfactory result in terms of viscosity. However, it may be considered to be a satisfactory result in terms of a viscosity, but nozzle drying due to solvent volatilization and nozzle clogging during ink-jetting, and reduction of a single layer thickness as time passed after ink-jetting may become worse and it is difficult to control a thickness deviation after curing. Thus, it is difficult to apply it to actual processes.

Therefore, a quantum dot ink that does not include a solvent is the most desirable form to be applied to an actual process. The current technique of applying a quantum dot itself to a solvent type composition is now limited to a certain extent.

In the case of a solvent-free curable composition (quantum dot ink composition), since an excessive amount of polymerizable compound is included, clogging and ejection failure by nozzle drying due to volatility, and single film thickness reduction due to volatilization of the ink composition jetted in the patterned partition wall pixel may be caused. Therefore, it is desirable to lower the viscosity of the solvent-free curable composition as much as possible.

Accordingly, efforts to lower the viscosity of the solvent-free curable composition by modifying a structure of the polymerizable compound such as increasing a molecular weight of the polymerizable monomer, introducing a chemical structure including a hydroxy group thereinto, or the like have been made. However, since a solvent-free curable composition having as low viscosity as desired has not been developed yet, one of the problems so far is there is no choice but to provide a curable composition with insufficient ink-jetting properties.

### DISCLOSURE

### Technical Problem

An embodiment provides a curable composition having a low viscosity, high light efficiency, high heat resistance, low out-gas characteristics, and high curing rate.

Another embodiment provides a cured layer manufactured using the curable composition.

Another embodiment provides a color filter including the cured layer.

Another embodiment provides a display device including the color filter.

### Technical Solution

An embodiment provides a curable composition including (A) a quantum dot surface-modified with at least two surface-modifying materials; and (B) a polymerizable compound, wherein the surface-modifying materials include a first surface-modifying material represented by Chemical Formula 1 and a second surface-modifying material represented by Chemical Formula 2.

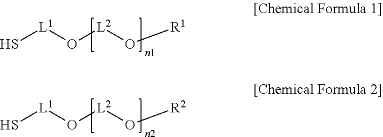

In Chemical Formula 1 and Chemical Formula 2,
R¹ is a substituted or unsubstituted C6 to C20 aryl group,
R² is a C1 to C20 alkyl group unsubstituted or substituted with a C1 to C10 alkyl group,
L¹ and L² are each independently a substituted or unsubstituted C1 to C20 alkylene group, and
n1 and n2 are each independently an integer from 2 to 20.

The first surface-modifying material and the second surface-modifying material may be included in a weight ratio of 30:70 to 70:30 based on the total amount of the quantum dot surface-modifying materials.

The first surface-modifying material may be represented by Chemical Formula 1-1.

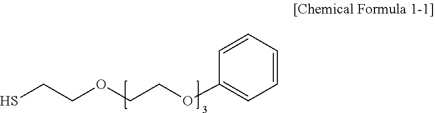

The second surface-modifying material may be represented by Chemical Formula 2-1.

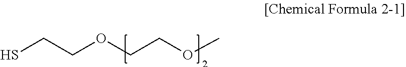

The quantum dot may be a quantum dot that is further surface-modified with a third surface-modifying material represented by Chemical Formula 3.

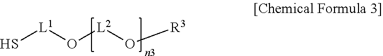

In Chemical Formula 3,
R³ is a C1 to C20 alkyl group substituted with a vinyl group,
L¹ and L² are each independently a substituted or unsubstituted C1 to C20 alkylene group, and
n3 is an integer from 2 to 20.

The first surface-modifying material and the second surface-modifying material may be included in an amount of 60 wt % to 90 wt % based on the total amount of the quantum dot surface-modifying materials.

The third surface-modifying material of the quantum dot surface-modifying materials may be included in an amount equal to or less than that of the first surface-modifying material or the second surface-modifying material.

The third surface-modifying material of the quantum dot surface-modifying materials may be included in an amount of 10 wt % to 40 wt % based on the total amount of the quantum dot surface-modifying materials.

The third surface-modifying material may be represented by Chemical Formula 3-1.

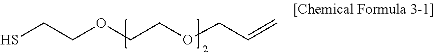

The quantum dot may be a quantum dot that is further surface-modified with a fourth surface-modifying material represented by Chemical Formula 4.

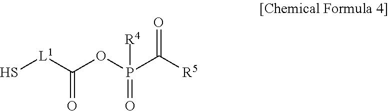

In Chemical Formula 4,
R⁴ and R⁵ are each independently a substituted or unsubstituted C6 to C20 aryl group, and
L¹ is a substituted or unsubstituted C1 to C20 alkylene group.

The fourth surface-modifying material of the quantum dot surface-modifying materials may be included in a smaller weight than the third surface-modifying material.

The fourth surface-modifying material of the quantum dot surface-modifying materials may be included in an amount of 1 wt % to 5 wt % based on the total amount of the quantum dot surface-modifying materials.

The fourth surface-modifying material may be represented by Chemical Formula 4-1.

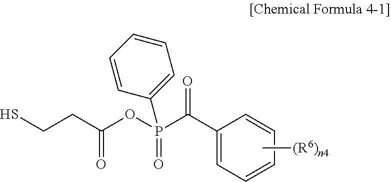

In Chemical Formula 4-1,
R⁶ is a substituted or unsubstituted C1 to C20 alkyl group, and
n4 is an integer from 1 to 5.

The first surface-modifying material may be included in an amount of 30 wt % to 70 wt %; the second surface-modifying material may be included in an amount of 15 wt % to 50 wt %; the third surface-modifying material may be included in an amount of 10 wt % to 30 wt %; and the fourth surface-modifying material may be included in an amount of 1 wt % to 5 wt % based on the total amount of the quantum dot surface-modifying materials.

The curable composition may be a solvent-free curable composition.

The solvent-free curable composition may include 5 wt % to 60 wt % of the quantum dot; and 40 wt % to 95 wt % of the polymerizable compound based on the total amount of the solvent-free curable composition.

The curable composition may further include a polymerization initiator, a light diffusing agent, a polymerization inhibitor, or a combination thereof.

The light diffusing agent may include barium sulfate, calcium carbonate, titanium dioxide, zirconia, or a combination thereof.

The curable composition may further include a solvent.

The curable composition may include 1 wt % to 40 wt % of the quantum dot; 1 wt % to 20 wt % of the polymerizable compound; and 40 wt % to 80 wt % of the solvent based on the total weight of the curable composition.

The curable composition may further include malonic acid; 3-amino-1,2-propanediol; a silane-based coupling agent; a leveling agent; a fluorine-based surfactant; or a combination thereof.

Another embodiment provides a cured layer manufactured using the curable composition.

Another embodiment provides a color filter including the cured layer.

Another embodiment provides a display device including the color filter.

Other embodiments of the present invention are included in the following detailed description.

### Advantageous Effects

The present invention may simultaneously accomplish low viscosity, high light efficiency, high heat resistance, low out-gas characteristics, and a high curing rate of a quantum dot-containing curable composition by surface-modifying the quantum dots in the quantum dot-containing curable composition are with a quantum dot surface-modifying material with a composition which has not been previously available.

### BEST MODE

Hereinafter, embodiments of the present invention are described in detail. However, these embodiments are exemplary, the present invention is not limited thereto and the present invention is defined by the scope of claims.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen atom by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid group or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” refers to inclusion of at least one heteroatom of N, O, S, and P, in the chemical formula.

As used herein, when specific definition is not otherwise provided, “(meth)acrylate” refers to both “acrylate” and “methacrylate”, and “(meth)acrylic acid” refers to “acrylic acid” and “methacrylic acid.”

As used herein, when specific definition is not otherwise provided, the term “combination” refers to mixing or copolymerization.

In the present specification, when a definition is not otherwise provided, hydrogen is bonded at the position when a chemical bond is not drawn in chemical formula where supposed to be given.

In addition, in the present specification, when a definition is not otherwise provided, “*” refers to a linking point with the same or different atom or chemical formula.

The quantum dot-containing curable composition according to the present invention may be prepared by surface-modifying the quantum dots with at least two surface-modifying materials but limiting structures of the surface-modifying materials and a weight ratio thereof to simultaneously accomplish high light efficiency, high heat resistance, low out-gas characteristics, and a high curing rate as well as effectively lower viscosity of the curable composition, compared with a conventional quantum dot-containing curable composition.

In general, dispersibility of the quantum dot-containing curable composition may be improved by adjusting a length of surface-modifying materials, and heat resistance of the quantum dot-containing curable composition may be improved by additionally using a thiol-based additive, a polymer binder, or the like, but all of these prior arts may be selected to have a specific component to improve one of dispersibility, heat resistance, and a curing rate of the quantum dot-containing curable composition, but there is a problem of deteriorating the other characteristics than the improved one by the selected component. In other words, with respect to viscosity, light efficiency, heat resistance, out-gas characteristics, and a curing rate of current quantum dot-containing curable compositions, there is no known technology for a quantum dot-containing curable composition simultaneously implementing low viscosity, high light efficiency, high heat resistance, low out-gas characteristics, and a high curing rate.

Accordingly, the inventors of the present invention have continued research and research and completed the present invention of a quantum dot-containing curable composition simultaneously excellently implementing the five characteristics (viscosity, light efficiency, heat resistance, out-gas characteristics, and curing rate). Since the surface-modifying materials respectively having different characteristics are not easy to coexist on the surface of quantum dots in an efficient ratio (weight ratio), research on structural changes and effective weight ratios is repeated by accumulating research and experiment data for many years, completing the present invention as a result of repeated efforts over the many years.

Hereinafter, each component constituting the curable composition according to an embodiment is described in detail.

### Quantum Dots

The quantum dots included in the curable composition according to an embodiment are surface-modified with at least two surface-modifying materials, wherein the surface-modifying materials include a first surface-modifying material represented by Chemical Formula 1 and a second surface-modifying material represented by Chemical Formula 2.

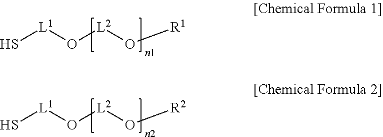

In Chemical Formula 1 and Chemical Formula 2,
R¹ is a substituted or unsubstituted C6 to C20 aryl group,
R² is a C1 to C20 alkyl group unsubstituted or substituted with a C1 to C10 alkyl group,
L¹ and L² are each independently a substituted or unsubstituted C1 to C20 alkylene group,
n1 and n2 are each independently an integer from 2 to 20.

As described above, the quantum dots simultaneously surface-modified with the first surface-modifying material and the second surface-modifying material may be easily prepared into highly-densified or highly-concentrated quantum dot dispersion (improve dispersibility of the quantum dots with respect to a polymerizable monomer described later), having significant influence on improving low viscosity and heat resistance and particularly, advantageously realizing a solvent-free curable composition. Furthermore, the quantum dots may be further surface-modified by a third surface-modifying material and/or a fourth surface-modifying material which is described later, to further lower light efficiency and improve a curing rate as well as an out-gas reduction effect.

For example, the first surface-modifying material and the second surface-modifying material may be included in a weight ratio of 30:70 to 70:30, for example 30:70 to 50:50 based on the total amount of the quantum dot surface-modifying materials. Specifically, when the quantum dot surface-modifying materials consists only of the first surface-modifying material and the second surface-modifying material, the first surface-modifying material and the second surface-modifying material may be included in a weight ratio of 30:70 to 70:30, for example, 30:70 to 50:50. On the other hand, when the quantum dot surface-modifying materials further include a third surface-modifying material and/or a fourth surface-modifying material to be described later in addition to the first surface-modifying material and the second surface-modifying material, the first surface-modifying material and the second surface-modifying material may be included in a weight ratio of 30:40 to 70:30, for example, 30:40 to 50:30 based on the total amount of the quantum dot surface-modifying materials. When the first surface-modifying material and the second surface-modifying material have the same weight ratio as described above, the low viscosity, high light efficiency, high heat resistance, low out-gas characteristics, and high curing rate of the curable composition according to an embodiment may be simultaneously implemented more advantageously.

For example, the first surface-modifying material may be represented by Chemical Formula 1-1, but is not necessarily limited thereto.

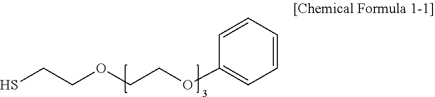

For example, the first surface-modifying material may be represented by Chemical Formula 2-1, but is not necessarily limited thereto.

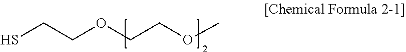

For example, the quantum dots may be further surface-modified with a third surface-modifying material represented by Chemical Formula 3. That is, the quantum dots may be surface-modified with the first surface-modifying material represented by Chemical Formula 1, the second surface-modifying material represented by Chemical Formula 2, and the third surface-modifying material represented by Chemical Formula 3.

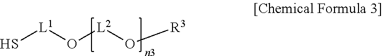

In Chemical Formula 3,
R³ is a C1 to C20 alkyl group substituted with a vinyl group,
L¹ and L² are each independently a substituted or unsubstituted C1 to C20 alkylene group, and
n3 is an integer from 2 to 20.

By further surface-modifying the quantum dots with the third surface-modifying material in addition to the first surface-modifying material and the second surface-modifying material, the optical properties and curing rate, in particular, the curing rate may be further improved without lowering heat resistance.

For example, when the quantum dot is further surface-modified with the third surface-modifying material in addition to the first surface-modifying material and the second surface-modifying material, the first surface-modifying material and the second surface-modifying material may be included in an amount of 60 wt % to 90 wt % based on the total amount of the quantum dot surface-modifying materials.

The third surface-modifying material of the quantum dot surface-modifying materials may be included in an amount equal to or less than that of the first surface-modifying material or the second surface-modifying material.

For example, the third surface-modifying material of the quantum dot surface-modifying materials may be included in an amount equal to or less than that of the first surface-modifying material or the second surface-modifying material.

For example, the third surface-modifying material of the quantum dot surface-modifying materials may be included in a smaller weight than the first surface-modifying material.

For example, the third surface-modifying material of the quantum dot surface-modifying materials may be included in an amount equal to or less than that of the second surface-modifying material.

For example, the third surface-modifying material of the quantum dot surface-modifying materials may be included in an amount of 10 wt % to 40 wt %, for example 10 wt % to 30 wt %, based on the total amount of the quantum dot surface-modifying materials.

For example, the third surface-modifying material may be represented by the following Chemical Formula 3-1, but is not necessarily limited thereto.

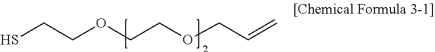

For example, when the surface-modifying material includes all of the first surface-modifying material, the second surface-modifying material, and the third surface-modifying material, the first surface-modifying material and second surface-modifying material may be included in an amount of 60 wt % to 90 wt %, for example 70 wt % to 85 wt % based on the total amount of the quantum dot surface-modifying materials.

For example, when the surface-modifying material includes all of the first surface-modifying material, the second surface-modifying material, and the third surface-modifying material, the first surface-modifying material, second surface-modifying material, and third surface-modifying material may be included in a weight ratio of 30 to 70:15 to 50:15 to 30.

For example, the quantum dot may be further surface-modified with a fourth surface-modifying material represented by Chemical Formula 4. That is, the quantum dots may be surface-modified with a first surface-modifying material represented by Chemical Formula 1, a second surface-modifying material represented by Chemical Formula 2, a third surface-modifying material represented by Chemical Formula 3, and a fourth surface-modifying material represented by Chemical Formula 4.

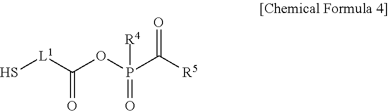

In Chemical Formula 4,
R⁴ and R⁵ are each independently a substituted or unsubstituted C6 to C20 aryl group, and
L¹ is a substituted or unsubstituted C1 to C20 alkylene group.

The quantum dots may be further surface-modified with the fourth surface-modifying material in addition to the first surface-modifying material, the second surface-modifying material, and the third surface-modifying material, thereby further improving optical properties, out-gas characteristics, and curing rate without lowering heat resistance.

For example, the fourth surface-modifying material of the quantum dot surface-modifying materials may be included in a smaller weight than the third surface-modifying material. Since the fourth surface-modifying material is included in a smaller weight than the third surface-modifying material, a significant increase in the viscosity of the curable composition according to the embodiment may be prevented.

For example, the fourth surface-modifying material may be included in an amount of 3 parts by weight to 50 parts by weight based on 100 parts by weight of the third surface-modifying material.

For example, the fourth surface-modifying material of the quantum dot surface-modifying materials may be included in an amount of 1 wt % to 5 wt % based on the total amount of the quantum dot surface-modifying materials.

For example, the fourth surface-modifying material may be represented by Chemical Formula 4-1, but is not necessarily limited thereto.

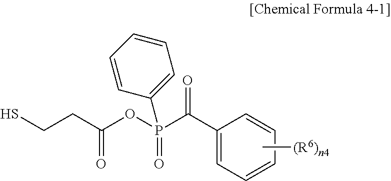

In Chemical Formula 4-1,
R⁶ is a substituted or unsubstituted C1 to C20 alkyl group, and
n4 is an integer from 1 to 5.

For example, when the surface-modifying material includes all of the first surface-modifying material, the second surface-modifying material, the third surface-modifying material, and the fourth surface-modifying material, the first surface-modifying material and the second surface-modifying material may be included in an amount of 60 wt % to 90 wt %, for example, 70 wt % to 85 wt %, based on the total amount of the quantum dot surface-modifying materials.

For example, when the surface-modifying material includes all of the first surface-modifying material, the second surface-modifying material, the third surface-modifying material, and the fourth surface-modifying material, the first surface-modifying material and the second surface-modifying material, the third surface-modifying material, and the fourth surface-modifying material may be included in a weight ratio of 30 to 70:15 to 50:10 to 30:1 to 5.

For example, the first surface-modifying material may be included in an amount of 30 wt % to 70 wt %; the second surface-modifying material may be included in an amount of 15 wt % to 50 wt %; the third surface-modifying material may be included in an amount of 10 wt % to 30 wt %; and the fourth surface-modifying material may be included in an amount of 1 wt % to 5 wt % based on the total amount of the quantum dot surface-modifying materials.

In addition, when the first surface-modifying material, the second surface-modifying material, the third surface-modifying material, and the fourth surface-modifying material are used together, the surface-modification of the quantum dots may be easier compared to the case of using a surface-modifying material having a different structure. When the quantum dots surface-modified with the surface-modifying materials are added to a polymerizable compound to be described later and stirred, a very transparent dispersion may be obtained, which is a measure of confirming that the surface-modification of the quantum dots is implemented very well.

For example, the quantum dots may have a maximum fluorescence emission wavelength in the range of 500 nm to 680 nm.

For example, when the curable composition according to an embodiment is a solvent-free curable composition, the quantum dots may be included in an amount of 5 wt % to 60 wt %, for example 10 wt % to 60 wt %, for example 20 wt % to 60 wt %, for example 30 wt % to 50 wt %. When the quantum dots are included within the above range, high light retention rate and light efficiency even after curing may be achieved.

For example, when the curable composition according to an embodiment is a curable composition including a solvent, the quantum dots may be included in an amount of 1 wt % to 40 wt %, for example 3 wt % to 30 wt %, based on the total amount of the curable composition. When the quantum dots are included within the above range, a light conversion rate is improved, and the pattern characteristics and developing characteristics are not impaired, and thus improved processability may be obtained.

Until now, curable compositions (inks) including quantum dots have been developed to be specialized in thiol-based binders or monomers having good compatibility with quantum dots, and furthermore, they are being commercialized.

For example, the quantum dots absorb light in a wavelength region of 360 nm to 780 nm, for example 400 nm to 780 nm and emits fluorescence in a wavelength region of 500 nm to 700 nm, for example 500 nm to 580 nm, or emits fluorescence in a wavelength region of 600 nm to 680 nm. That is, the quantum dots may have a maximum fluorescence emission wavelength (fluorescence λₑₘ) at 500 nm to 680 nm.

The quantum dots may independently have a full width at half maximum (FWHM) of 20 nm to 100 nm, for example 20 nm to 50 nm. When the quantum dots have a full width at half maximum (FWHM) of the ranges, color reproducibility is increased when used as a color material in a color filter due to high color purity.

The quantum dots may independently be an organic material, an inorganic material, or a hybrid (mixture) of an organic material and an inorganic material.

The quantum dots may each independently be composed of a core and a shell surrounding the core, and the core and the shell may independently have a structure of a core, a core/shell, a core/first shell/second shell, an alloy, an alloy/shell, or the like, which is composed of Group II-IV, Group III-V, and the like, but are not limited thereto.

For example, the core may include at least at least one material selected from CdS, CdSe, CdTe, ZnS, ZnSe, ZnTe, HgS, HgSe, HgTe, GaN, GaP, GaAs, InP, InAs, and an alloy thereof, but is not necessarily limited thereto. The shell surrounding the core may include at least at least one material selected from CdSe, ZnSe, ZnS, ZnTe, CdTe, PbS, TiO, SrSe, HgSe, and an alloy thereof, but is not necessarily limited thereto.

In an embodiment, since an interest in an environment has been recently much increased over the whole world, and a restriction of a toxic material also has been fortified, a cadmium-free light emitting material (InP/ZnS, InP/ZnSe/ZnS, etc.) having little low quantum efficiency (quantum yield) but being environmentally-friendly instead of a light emitting material having a cadmium-based core is used, but not necessarily limited thereto.

In the case of the quantum dots of the core/shell structure, an entire size including the shell (an average particle diameter) may be 1 nm to 15 nm, for example, 5 nm to 15 nm.

For example, the quantum dots may independently include red quantum dots, green quantum dots, or a combination thereof. The red quantum dots may independently have an average particle diameter of 10 nm to 15 nm. The green quantum dots may independently have an average particle diameter of 5 nm to 8 nm.

On the other hand, for the dispersion stability of the quantum dots, the curable composition according to an embodiment may further include a dispersant. The dispersant helps uniform dispersibility of light conversion materials such as quantum dots in the curable composition and may include a non-ionic, anionic, or cationic dispersant. Specifically, the dispersant may be polyalkylene glycol or esters thereof, a polyoxy alkylene, a polyhydric alcohol ester alkylene oxide addition product, an alcohol alkylene oxide addition product, a sulfonate ester, a sulfonate salt, a carboxylate ester, a carboxylate salt, an alkyl amide alkylene oxide addition product, an alkyl amine and the like, and they may be used alone or in a mixture of two or more. The dispersant may be used in an amount of 0.1 wt % to 100 wt %, for example 10 wt % to 20 wt % based on the solid content of the light conversion material such as quantum dots.

### Polymerizable Compound

The curable composition according to the embodiment includes a polymerizable compound, and the polymerizable compound may have a carbon-carbon double bond at the terminal end thereof.

The polymerizable compound having the carbon-carbon double bond at the terminal end may be included in an amount of 40 wt % to 95 wt %, for example 50 wt % to 90 wt % based on the total amount of the solvent-free curable composition. When the polymerizable compound having a carbon-carbon double bond at the terminal end is included within the ranges, a solvent-free curable composition having a viscosity that enables ink-jetting may be prepared and the quantum dots in the prepared solvent-free curable composition may have improved dispersibility, thereby improving optical characteristics.

For example, the polymerizable compound having a carbon-carbon double bond at the terminal end may have a molecular weight of 170 g/mol to 1,000 g/mol. When the molecular weight of the polymerizable compound having a carbon-carbon double bond at the terminal end is within the above range, it may be advantageous for ink-jetting because the viscosity of the composition is not increased without impairing the optical properties of the quantum dots.

For example, the polymerizable compound having a carbon-carbon double bond at the terminal end may be represented by Chemical Formula 6, but is not necessarily limited thereto.

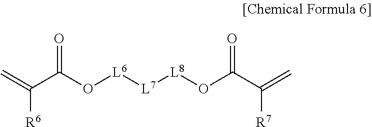

In Chemical Formula 6,
R⁶ and R⁷ are each independently a hydrogen atom or a substituted or unsubstituted C1 to C10 alkyl group,
L⁶ and L⁸ are each independently a single bond or a substituted or unsubstituted C1 to C10 alkylene group, and
L⁷ is a substituted or unsubstituted C1 to C10 alkylene group, a substituted or unsubstituted C3 to C20 cycloalkylene group, or an ether group (*—O—*).

For example, the polymerizable compound having a carbon-carbon double bond at the terminal end may be represented by Chemical Formula 6-1 or 6-2, but is not necessarily limited thereto.

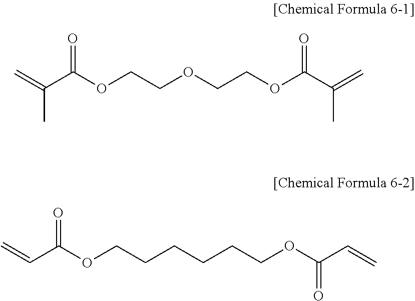

For example, the polymerizable compound having the carbon-carbon double bond at the terminal end may further include ethylene glycoldiacrylate, triethylene glycoldiacrylate, 1,4-butanedioldiacrylate, 1,6-hexanedioldiacrylate, neopentylglycoldiacrylate, pentaerythritoldiacrylate, pentaerythritoltriacrylate, dipentaerythritoldiacrylate, dipentaerythritoltriacrylate, dipentaerythritolpentaacrylate, pentaerythritolhexaacrylate, bisphenol A diacrylate, trimethyloIpropanetriacrylate, novolacepoxyacrylate, ethylene glycoldimethacrylate, triethylene glycoldimethacrylate, propylene glycoldimethacrylate, 1,4-butanedioldimethacrylate, 1,6-hexanedioldimethacrylate, or a combination thereof, besides the aforementioned compound represented by Chemical Formula 6-1 or Chemical Formula 6-2.

In addition, the polymerizable compound having the carbon-carbon double bond at the terminal end may further include a monomer generally used in conventional thermosetting or photocurable compositions, and for example, the monomer may further include an oxetane-based compound such as bis[1-ethyl (3-oxetanyl)]methyl ether.

In addition, when the curable composition includes a solvent, the polymerizable compound may be included in an amount of 1 wt % to 20 wt %, 1 wt % to 15 wt %, for example 5 wt % to 15 wt % based on the total amount of the curable composition. When the polymerizable compound is included within the above range, optical properties of the quantum dots may be improved.

### Light Diffusing Agent

The curable composition according to an embodiment may further include a light diffusing agent.

For example, the light diffusing agent may include barium sulfate (BaSO₄), calcium carbonate (CaCO₃), titanium dioxide (TiO₂), zirconia (ZrO₂), or a combination thereof.

The light diffusing agent may reflect unabsorbed light in the aforementioned quantum dots and allows the quantum dots to absorb the reflected light again. That is, the light diffusing agent may increase an amount of light absorbed by the quantum dots and increase light conversion efficiency of the curable composition.

The light diffusing agent may have an average particle diameter (D₅₀) of 150 nm to 250 nm, specifically 180 nm to 230 nm. When the average particle diameter of the light diffusing agent is within the ranges, it may have a better light diffusing effect and increase light conversion efficiency.

The light diffusing agent may be included in an amount of 1 wt % to 20 wt %, for example 2 wt % to 15 wt %, for example 3 wt % to 10 wt % based on the total amount of the curable composition. When the light diffusing agent is included in an amount of less than 1 wt % based on the total amount of the curable composition, it is difficult to expect an effect of improving the light conversion efficiency by using the light diffusing agent, and when it is included in an amount of greater than 20 wt %, the quantum dot sedimentation problem may occur.

### Polymerization Initiator

The curable composition according to an embodiment may further include a polymerization initiator, for example, a photopolymerization initiator, a thermal polymerization initiator, or a combination thereof.

The photopolymerization initiator is a generally-used initiator for a photosensitive resin composition, for example an acetophenone-based compound, a benzophenone-based compound, a thioxanthone-based compound, a benzoin-based compound, a triazine-based compound, an oxime-based compound, an aminoketone-based compound, and the like, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloroacetophenone, p-t-butyldichloroacetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be O-acyloxime-based compound, 2-(O-benzoyloxime)-1-[4-(phenylthio)phenyl]-1,2-octandione, 1-(0-acetyloxime)-1-[9-ethyl-6-(2-methylbenzoyl)-9H-carbazol-3-yl]ethanone, 0-ethoxycarbonyl-α-oxyamino-1-phenylpropan-1-one, and the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

Examples of the aminoketone-based compound may be 2-benzyl-2-dimethylamino-1-(4-morpholinophenyl)-butanone-1, and the like.

The photopolymerization initiator may further include a carbazole-based compound, a diketone-based compound, a sulfonium borate-based compound, a diazo-based compound, an imidazole-based compound, a biimidazole-based compound, and the like, besides the compounds.

The photopolymerization initiator may be used with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

Examples of the thermal polymerization initiator may be peroxide, specifically benzoyl peroxide, dibenzoyl peroxide, lauryl peroxide, dilauryl peroxide, di-tert-butyl peroxide, cyclohexane peroxide, methyl ethyl ketone peroxide, hydroperoxide (e.g., tert-butyl hydroperoxide, cumene hydroperoxide), dicyclohexyl peroxydicarbonate, 2,2-azo-bis(isobutyronitrile), t-butyl perbenzoate, and the like, for example 2,2′-azobis-2-methylpropinonitrile, but are not necessarily limited thereto, and any of which is well known in the art may be used.

The polymerization initiator may be included in an amount of 0.1 wt % to 5 wt %, for example 1 wt % to 4 wt % based on the total amount of the curable composition. When the polymerization initiator is included in the ranges, it is possible to obtain excellent reliability due to sufficient curing during exposure or thermal curing and to prevent deterioration of transmittance due to non-reaction initiators, thereby preventing deterioration of optical properties of the quantum dots.

### Binder Resin

The curable composition according to an embodiment may further include a binder resin.

The binder resin may include an acryl-based resin, a cardo-based resin, an epoxy resin, or a combination thereof.

The acryl-based resin may be a copolymer of a first ethylenic unsaturated monomer and a second ethylenic unsaturated monomer that is copolymerizable therewith, and may be a resin including at least one acryl-based repeating unit.

Specific examples of the acryl-based binder resin may be polybenzylmethacrylate, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, but are not limited thereto, and may be used alone or as a mixture of two or more.

A weight average molecular weight of the acryl-based binder resin may be 5,000 g/mol to 15,000 g/mol. When the acryl-based binder resin has a weight average molecular weight within the ranges, close-contacting properties to a substrate, physical and chemical properties are improved, and a viscosity is appropriate.

The acryl-based resin may have an acid value of 80 mgKOH/g to 130 mgKOH/g. When the acryl-based resin has an acid value within the range, a pixel pattern may have excellent resolution.

The cardo-based resin may be used in a conventional curable resin (or photosensitive resin) composition, and may be, for example, used as disclosed in Korean Patent Application Laid-Open No. 10-2018-0067243, but is not limited thereto.

The cardo-based resin may be, for example prepared by mixing at least two of a fluorene-containing compound such as 9,9-bis(4-oxiranylmethoxyphenyl)fluorene; an anhydride compound such as benzenetetracarboxylic acid dianhydride, naphthalenetetracarboxylic acid dianhydride, biphenyltetracarboxylic acid dianhydride, benzophenonetetracarboxylic acid dianhydride, pyromellitic dianhydride, cyclobutanetetracarboxylic acid dianhydride, perylenetetracarboxylic acid dianhydride, tetrahydrofurantetracarboxylic acid dianhydride, and tetrahydrophthalic anhydride; a glycol compound such as ethylene glycol, propylene glycol, and polyethylene glycol; an alcohol compound such as methanol, ethanol, propanol, n-butanol, cyclohexanol, and benzylalcohol; a solvent-based compound such as propylene glycol methylethylacetate, and N-methylpyrrolidone; a phosphorus compound such as triphenylphosphine; and an amine or ammonium salt compound such as tetramethylammonium chloride, tetraethylammonium bromide, benzyldiethylamine, triethylamine, tributylamine, or benzyltriethylammonium chloride.

A weight average molecular weight of the cardo-based binder resin may be 500 g/mol to 50,000 g/mol, for example 1,000 g/mol to 30,000 g/mol. When the weight average molecular weight of the cardo-based binder resin is within the ranges, a satisfactory pattern may be formed without a residue during a production of a cured layer and without losing a film thickness during development of the solvent-type curable composition.

When the binder resin is a cardo-based resin, the developability of the curable composition, particularly the photosensitive resin composition, including the binder resin is improved, and the sensitivity during photocuring is good, so that the fine pattern formation property is improved.

The epoxy resin may be a monomer or oligomer that is capable of being polymerized by heat, and may include a compound having a carbon-carbon unsaturated bond and a carbon-carbon cyclic bond.

The epoxy resin may include, but is not limited to, a bisphenol A-type epoxy resin, a bisphenol F-type epoxy resin, a phenol novolac-type epoxy resin, a cyclic aliphatic epoxy resin, and an aliphatic polyglycidyl ether.

Currently available products thereof may include bisphenyl epoxy resins such as YX4000, YX4000H, YL6121H, YL6640, or YL6677 from Yuka Shell Epoxy Co., Ltd.; cresol novolac-type epoxy resins such as EOCN-102, EOCN-103S, EOCN-104S, EOCN-1020, EOCN-1025, and EOCN-1027 from Nippon Kayaku Co., Ltd. and EPIKOTE 180S75 from Yuka Shell Epoxy Co., Ltd.; bisphenol A epoxy resins such as EPIKOTE 1001, 1002, 1003, 1004, 1007, 1009, 1010, and 828 from Yuka Shell Epoxy Co., Ltd.; bisphenol F-type epoxy resins such as EPIKOTE 807 and 834 from Yuka Shell Epoxy Co., Ltd.; phenol novolac-type epoxy resins such as EPIKOTE 152, 154, and 157H65 from Yuka Shell Epoxy Co., Ltd. and EPPN 201, 202 from Nippon Kayaku Co., Ltd.; other cyclic aliphatic epoxy resins such as CY175, CY177 and CY179 from CIBA-GEIGY A.G, ERL-4234, ERL-4299, ERL-4221, and ERL-4206 from U.C.C, Shodyne 509 from Showa Denko K.K., ARALDITE CY-182, CY-192 and CY-184 from CIBA-GEIGY A.G, Epichron 200 and 400 from Dainippon Ink and Chemicals, Inc., EPIKOTE 871, 872 and EP1032H60 from Yuka Shell Epoxy Co., Ltd., ED-5661 and ED-5662 from Celanese Coatings Co., Ltd.; aliphatic polyglycidylethers such as EPIKOTE 190P and 191P from Yuka Shell Epoxy Co., Ltd., Epolite 100MF from Kyoesha Yushi Co., Ltd., Epiol TMP from Nippon Yushi Co., Ltd., and the like.

For example, when the curable composition according to an embodiment is a solvent-free curable composition, the binder resin may be included in an amount of 0.5 wt % to 10 wt %, for example 1 wt % to 5 wt %, based on the total amount of the curable composition. In this case, heat resistance and chemical resistance of the solvent-free curable composition may be improved, and storage stability of the composition may also be improved.

For example, when the curable composition according to an embodiment is a curable composition including a solvent, the binder resin may be included in an amount of 1 wt % to 30 wt %, for example 3 wt % to 20 wt %, based on the total amount of the curable composition. In this case, pattern characteristics, heat resistance and chemical resistance may be improved.

Other Additives For stability and dispersion improvement of the quantum dot, the curable composition according to an embodiment may further include a polymerization inhibitor.

The polymerization inhibitor may include a hydroquinone-based compound, a catechol-based compound, or a combination thereof, but is not necessarily limited thereto. When the curable composition according to an embodiment further includes the hydroquinone-based compound, the catechol-based compound, or the combination thereof, room-temperature crosslinking during exposure after printing (coating) the curable composition may be prevented.

For example, the hydroquinone-based compound, catechol-based compound or combination thereof may include hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminium, or a combination thereof, but is not necessarily limited thereto.

The hydroquinone-based compound, catechol-based compound, or combination thereof may be used in the form of a dispersion, and the polymerization inhibitor in the dispersion form may be included in an amount of 0.001 wt % to 3 wt %, for example 0.01 wt % to 2 wt % based on the total amount of the curable composition. When the polymerization inhibitor is included within the above range, the problem of aging at room temperature may be solved, and at the same time, reduction of sensitivity and surface peeling may be prevented.

In addition, the curable composition according to an embodiment may include may further include malonic acid; 3-amino-1,2-propanediol; a silane-based coupling agent; a leveling agent; a fluorine-based surfactant; or a combination thereof in order to improve heat resistance and reliability.

For example, the curable composition according to an embodiment may further include a silane-based coupling agent having a reactive substituent such as a vinyl group, a carboxyl group, a methacryloxy group, an isocyanate group, an epoxy group, and the like in order to improve close-contacting properties with a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxy silane, γ-glycidoxy propyl trimethoxysilane, β-epoxycyclohexyl)ethyl trimethoxy silane, and the like, and these may be used alone or in a mixture of two or more.

The silane-based coupling agent may be included in an amount of 0.01 parts by weight to 10 parts by weight based on 100 parts by weight of the curable composition. When the silane-based coupling agent is included within the range, close-contacting properties, storage capability, and the like are improved.

In addition, the curable composition may further include a surfactant, for example a fluorine-based surfactant as needed in order to improve coating properties and inhibit generation of spots, that is, improve leveling performance.

The fluorine-based surfactant may have a low weight average molecular weight of 4,000 g/mol to 10,000 g/mol, and specifically 6,000 g/mol to 10,000 g/mol. In addition, the fluorine-based surfactant may have a surface tension of 18 mN/m to 23 mN/m (measured in 0.1% polyethylene glycol monomethylether acetate (PGMEA) solution). When the fluorine-based surfactant has a weight average molecular weight and a surface tension within the ranges, leveling performance may be further improved, and excellent characteristics may be provided when slit coating as high-speed coating is applied since film defects may be less generated by preventing a spot generation during the high-speed coating and suppressing a vapor generation.

Examples of the fluorine-based surfactant may be, BM-1000®, and BM-1100® (BM Chemie Inc.); MEGAFACE F 142D®, F 172®, F 173®, and F 183® Dainippon Ink Kagaku Kogyo Co., Ltd.); FULORAD FC-135®, FULORAD FC-170C®, FULORAD FC-430®, and FULORAD FC-431® (Sumitomo 3M Co., Ltd.); SURFLON S-112®, SURFLON S-113®, SURFLON S-131®, SURFLON S-141®, and SURFLON S-145® (ASAHI Glass Co., Ltd.); and SH-28PA®, SH-190®, SH-193®, SZ-6032®, and SF-8428®, and the like (Toray Silicone Co., Ltd.); F-482, F-484, F-478, F-554, and the like from DIC Co., Ltd.

In addition, the curable composition according to an embodiment may include a silicone-based surfactant in addition to the fluorine-based surfactant. Specific examples of the silicone-based surfactant may be TSF400, TSF401, TSF410, TSF4440, and the like of Toshiba Silicone Co., Ltd., but are not limited thereto.

The surfactant may be included in an amount of 0.01 parts by weight to 5 parts by weight, for example 0.1 parts by weight to 2 parts by weight based on 100 parts by weight of the curable composition. When the surfactant is included within the ranges, foreign materials are less produced in a sprayed composition.

In addition, the curable composition according to an embodiment may further include other additives such as an antioxidant, a stabilizer, and the like in a predetermined amount, unless properties are deteriorated.

### Solvent

Meanwhile, the curable composition according to an embodiment may further include a solvent.

The solvent may for example include alcohols such as methanol, ethanol, and the like; glycol ethers such as ethylene glycol methylether, ethylene glycol ethylether, propylene glycol methylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethylether acetate, propylene glycol propylether acetate, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; hydroxy acetic acid alkyl esters such as methyl hydroxyacetate, ethyl hydroxyacetate, butyl hydroxyacetate, and the like; acetic acid alkoxyalkyl esters such as methoxymethyl acetate, methoxyethyl acetate, methoxybutyl acetate, ethoxymethyl acetate, ethoxyethyl acetate, and the like; 3-hydroxypropionic acid alkyl esters such as methyl 3-hydroxypropionate, ethyl 3-hydroxypropionate, and the like; 3-alkoxypropionic acid alkyl esters such as methyl 3-methoxypropionate, ethyl 3-methoxypropionate, ethyl 3-ethoxypropionate, methyl 3-ethoxypropionate, and the like; 2-hydroxypropionic acid alkyl ester such as methyl 2-hydroxypropionate, ethyl 2-hydroxypropionate, propyl 2-hydroxypropionate, and the like; 2-alkoxypropionic acid alkyl esters such as methyl 2-methoxypropionate, ethyl 2-methoxypropionate, ethyl 2-ethoxypropionate, methyl 2-ethoxypropionate, and the like; 2-hydroxy-2-methylpropionic acid alkyl esters such as methyl 2-hydroxy-2-methylpropionate, ethyl 2-hydroxy-2-methylpropionate, and the like; 2-alkoxy-2-methylpropionic acid alkyl esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate, and the like; or ketonate esters such as ethyl pyruvate, and the like, and in addition, may be N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like, but is not limited thereto.

For example, the solvent may be desirably glycol ethers such as ethylene glycol monoethylether, ethylene diglycolmethylethylether, and the like; ethylene glycol alkylether acetates such as ethyl cellosolve acetate, and the like; esters such as 2-hydroxy ethyl propionate, and the like; carbitols such as diethylene glycol monomethylether, and the like; propylene glycol alkylether acetates such as propylene glycol monomethylether acetate, propylene glycol propylether acetate, and the like; alcohols such as ethanol, and the like, or a combination thereof.

For example, the solvent may be a polar solvent including propylene glycol monomethylether acetate, dipropylene glycol methylether acetate, ethanol, ethylene glycoldimethylether, ethylenediglycolmethylethylether, diethylene glycoldimethylether, 2-butoxyethanol, N-methylpyrrolidine, N-ethylpyrrolidine, propylene carbonate, γ-butyrolactone, or a combination thereof.

The solvent may be included in an amount of 40 wt % to 80 wt %, for example 45 wt % to 80 wt %, based on the total amount of the curable composition. When the solvent is within the range, the solvent-type curable composition has appropriate viscosity and thus may have excellent coating property when coated in a large area through spin-coating and slit-coating.

Another embodiment provides a cured layer manufactured using the curable composition, a color filter including the cured layer, and a display device including the color filter.

One of methods of manufacturing the cured layer may include coating the curable composition on a substrate using an ink-jet spraying method to form a pattern (S1); and curing the pattern (S2).

### (S1) Formation of Pattern

The curable composition may desirably be coated to be 0.5 μm to 20 μm on a substrate in an ink-jet spraying method. The ink-jet spraying method may form a pattern by spraying a single color per each nozzle and thus repeating the spraying as many times as the needed number of colors, but the pattern may be formed by simultaneously spraying the needed number of colors through each ink-jet nozzle in order to reduce processes.

### (S2) Curing

The obtained pattern is cured to obtain a pixel. Herein, the curing method may be thermal curing or photocuring process. The thermal curing process may be performed at greater than or equal to 100° C., desirably, in a range of 100° C. to 300° C., and more desirably, in a range of 160° C. to 250° C. The photocuring process may include irradiating an actinic ray such as a UV ray of 190 nm to 450 nm, for example 200 nm to 500 nm. The irradiating is performed by using a light source such as a mercury lamp with a low pressure, a high pressure, or an ultrahigh pressure, a metal halide lamp, an argon gas laser, and the like. An X ray, an electron beam, and the like may be also used as needed.

The other method of manufacturing the cured layer may include manufacturing a cured layer using the aforementioned curable composition by a lithographic method as follows.

### (1) Coating and Film Formation

The curable composition is coated to have a desired thickness, for example, a thickness ranging from 2 μm to 10 μm, on a substrate which undergoes a predetermined pretreatment, using a spin or slit coating method, a roll coating method, a screen-printing method, an applicator method, and the like. Then, the coated substrate is heated at a temperature of 70° C. to 90° C. for 1 minute to 10 minutes to remove a solvent and to form a film.

### (2) Exposure

The resultant film is irradiated by an actinic ray such as a UV ray of 190 nm to 450 nm, for example 200 nm to 500 nm after putting a mask with a predetermined shape to form a desired pattern. The irradiating is performed by using a light source such as a mercury lamp with a low pressure, a high pressure, or an ultrahigh pressure, a metal halide lamp, an argon gas laser, and the like. An X ray, an electron beam, and the like may be also used as needed.

Exposure process uses, for example, a light dose of 500 mJ/cm² or less (with a 365 nm sensor) when a high-pressure mercury lamp is used. However, the light dose may vary depending on types of each component of the curable composition, its combination ratio, and a dry film thickness.

### (3) Development

After the exposure process, an alkali aqueous solution is used to develop the exposed film by dissolving and removing an unnecessary part except the exposed part, forming an image pattern. In other words, when the alkali developing solution is used for the development, a non-exposed region is dissolved, and an image color filter pattern is formed.

### (4) Post-Treatment

The developed image pattern may be heated again or irradiated by an actinic ray and the like for curing, in order to accomplish excellent quality in terms of heat resistance, light resistance, close-contacting properties, crack-resistance, chemical resistance, high strength, storage stability, and the like.

Hereinafter, the present invention is illustrated in more detail with reference to examples. These examples, however, are not in any sense to be interpreted as limiting the scope of the invention.

### MODE FOR INVENTION

### (Preparation of Surface-Modified Quantum Dots)

After putting a magnetic bar in a 3-neck round-bottomed flask, green quantum dot dispersion solution (InP/ZnSe/ZnS, Hansol Chemical; quantum dot solid content of 23 wt %) was put therein. Herein, surface modifying materials were added according to the composition of Table 1, and stirred at 80° C. in a nitrogen atmosphere. When the reaction was completed, after decreasing the temperature down to room temperature (23° C.) the quantum dot reaction solution was added to cyclohexane, catching precipitates. The precipitates were separated from the cyclohexane through centrifugation and then, sufficiently dried in a vacuum oven for one day, obtaining green surface-modified quantum dots.

TABLE 1
(wt %)

| | First | Second | Third | Fourth |
|---|---|---|---|---|
| | surface- | surface- | surface- | surface- |
| | modifying | modifying | modifying | modifying |
| | material | material | material | material |
| Preparation Example 1 | 70 | 30 | 0 | 0 |
| Preparation Example 2 | 70 | 15 | 15 | 0 |
| Preparation Example 3 | 70 | 15 | 10 | 5 |
| Preparation Example 4 | 70 | 15 | 13 | 2 |
| Preparation Example 5 | 70 | 15 | 14 | 1 |
| Preparation Example 6 | 50 | 50 | 0 | 0 |
| Preparation Example 7 | 50 | 30 | 20 | 0 |
| Preparation Example 8 | 50 | 30 | 15 | 5 |
| Preparation Example 9 | 50 | 30 | 18 | 2 |
| Preparation Example 10 | 50 | 30 | 19 | 1 |
| Preparation Example 11 | 30 | 50 | 20 | 0 |
| Preparation Example 12 | 30 | 50 | 15 | 5 |
| Preparation Example 13 | 30 | 50 | 18 | 2 |
| Preparation Example 14 | 30 | 50 | 19 | 1 |
| Preparation Example 15 | 30 | 40 | 30 | 0 |
| Preparation Example 16 | 30 | 40 | 25 | 5 |
| Preparation Example 17 | 30 | 40 | 28 | 2 |
| Preparation Example 18 | 30 | 40 | 29 | 1 |
| Comparative Preparation | 100 | 0 | 0 | 0 |
| Example 1 | | | | |
| Comparative Preparation | 0 | 100 | 0 | 0 |
| Example 2 | | | | |
| Comparative Preparation | 0 | 0 | 100 | 0 |
| Example 3 | | | | |
| Comparative Preparation | 0 | 0 | 0 | 100 |
| Example 4 | | | | |

### Synthesis of the Compound Represented by Chemical Formula 1-1 (First Surface-Modifying Material):

PH-4 (Hannong Chemical Inc.) was put in a 2-neck round-bottomed flask and then, sufficiently dissolved in 300 mL of tetrahydrofuran (THF). 15.4 g of NaOH and 100 mL of water were injected thereinto at 0° C. and then, sufficiently dissolved, until a clear solution was obtained. A solution obtained by dissolving 73 g of para-toluene sulfonic chloride in 100 mL of THF was slowly injected thereinto at 0° C. Injection was carried out for 1 hour, and the obtained mixture was stirred at room temperature for 12 hours. When the reaction was completed, an excessive amount of methylene chloride was added thereto and then, stirred, and a NaHCO₃ saturated solution was added thereto, which was followed by extraction, titration, and water removal. After removing the solvent, the residue was dried in a dry oven for 24 hours. 50 g of the dried product was put in a 2-neck round-bottomed flask and sufficiently stirred in 300 mL of ethanol. Subsequently, 27 g of thiourea was added thereto and dispersed therein and then, refluxed at 80° C. for 12 hours. Then, an aqueous solution prepared by dissolving 4.4 g of NaOH in 20 mL of water was injected thereinto, while further stirred for 5 hours, an excessive amount of methylene chloride was added thereto, and then, a hydrochloric acid aqueous solution was added thereto, which was sequentially followed by extraction, titration, water removal, and solvent removal. The obtained product was dried in a vacuum oven for 24 hours, obtaining a compound represented by Chemical Formula 1-1.

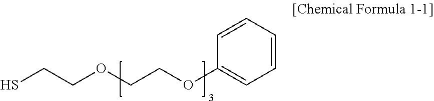

### Synthesis of the Compound Represented by Chemical Formula 2-1 (Second Surface-Modifying Material):

100 g of triethylene glycol monomethyl ether was put in a 2-neck round-bottomed flask and sufficiently dissolved in 300 mL of THF. 36.6 g of NaOH and 100 mL of water were injected thereinto at 0° C. and then, sufficiently dissolved, until a clear solution was obtained. A solution obtained by dissolving 127 g of para-toluene sulfonic chloride in 100 mL of THF was slowly injected thereinto at 0° C. Injection was carried out for 1 hour, and the obtained mixture was stirred at room temperature for 12 hours. When the reaction was completed, an excessive amount of methylene chloride was added thereto and then, stirred, and a NaHCO₃ saturated solution was added thereto, which was followed by extraction, titration, and water removal. After removing the solvent, the residue was dried in a dry oven for 24 hours. 50 g of the dried product was put in a 2-neck round-bottomed flask and sufficiently stirred in 300 mL of ethanol. Subsequently, 58 g of thiourea was added thereto and dispersed therein and then, refluxed at 80° C. for 12 hours. Then, an aqueous solution prepared by dissolving 18.5 g of NaOH in 20 mL of water was injected thereinto, while further stirred for 5 hours, an excessive amount of methylene chloride was added thereto, and then, a hydrochloric acid aqueous solution was added thereto, which was sequentially followed by extraction, titration, water removal, and solvent removal. The obtained product was dried in a vacuum oven for 24 hours, obtaining a compound represented by Chemical Formula 2-1.

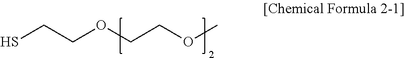

### Synthesis of Compound Represented by Chemical Formula 3-1 (Third Surface-Modifying Material):

100 g of triethylene glycol and 81 g of allyl bromide were dissolved in DMF in a condenser-2-neck round-bottomed flask, and 26 g of NaH (60%) was divided into several portions and slowly added thereto. The mixture was stirred under a nitrogen atmosphere for 5 minutes and then, additionally stirred at 60° C. for 12 hours. When a reaction was completed, the resultant was cooled to room temperature. 200 mL of water and 500 mL of methylene chloride were added thereto to perform three times extractions, and then, the water alone was used to perform twice extractions, and MgSO₄ was used to remove moisture therefrom. After concentrating the solvent and drying a product therefrom in a drying oven for 24 hours, 50 g thereof was put in a 2-neck round-bottomed flask, and 200 mL of THF and 100 mL of water were added thereto. Subsequently, 15.8 g of NaOH was added thereto and well dissolved therein. After connecting a dropping funnel to the flask, a solution prepared by dissolving 60 g of para-toluene sulfonic chloride in 120 mL of THF was put in the dropping funnel and then, slowly injected thereinto at 0° C. Subsequently, the mixture was additionally stirred for 12 hours at room temperature. When a reaction was completed, after adding 200 mL of water and 100 mL of a saturated NaHCO₃ solution thereto, 300 mL of a methylene chloride solvent was added thereto to sequentially perform neutralization, extraction, removal of moisture, and concentration of the solvent. A product therefrom was vacuum-dried for 24 hours, and 50 g thereof was put again in the condenser-2-neck flask and well dissolved in 300 mL of ethanol. Subsequently, 5 equivalents of thiourea was added thereto and then, stirred for 12 hours at 80° C. Next, 3 equivalents of a NaOH aqueous solution was added thereto and then, additionally stirred for 6 hours, completing the reaction. Then, 100 mL of water, 100 mL of a diluted hydrochloric acid aqueous solution, and 300 mL of methylene chloride were added thereto to sequentially perform neutralization, extraction, moisture removal, and solvent concentration. A product therefrom was vacuum-dried for 24 hours, obtaining a compound represented by Chemical Formula 3-1.

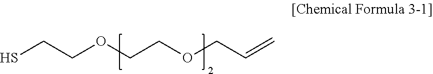

### Synthesis of Compound Represented by Chemical Formula 4-1 (Fourth Surface-Modifying Material):

5 g of a TPO-L initiator was dissolved in 300 mL of an MEK (Methyl Ethyl Ketone) solvent, and 1 equivalent of NaI was injected thereinto and then, stirred at 60° C. for 12 hours. When a reaction was completed, the resultant was suction-filtered, obtaining a white solid. 500 mL of deionized water was added thereto to redissolve it. 1 equivalent of a 50% sulfuric acid aqueous solution was slowly added thereto in a drop wise fashion and then, stirred for 1 hour. After confirming that PH reached 1 or so, the reprecipitated powder was obtained through filtering. After installing a dean-stark, 200 mL of toluene was added thereto and then, stirred for 12 hours at 100° C. to all remove moisture. The obtained white solid, TPO—OH was vacuum-dried for 24 hours. 5 g of the TPO—OH initiator was dispersed in 50 mL of methylene chloride in a two-neck flask. Subsequently, 4.5 g of SOCl₂ was slowly injected thereinto. After confirming that formation of bubbles as a proof of a reaction was confirmed through one inlet of the flask with a bubbler, if dispersion was slowly cleared after a while, which shows that the reaction well progressed. The resultant was stirred for 12 hours at room temperature, completing the reaction. After concentrating the solvent under vacuum, 50 mL of toluene was added again thereto, and the solvent was additionally concentrated. A product therefrom was vacuum-dried for 24 hours, and 100 mL of toluene was added thereto in the flask to redissolve it. 1.73 g of mercapto propionic acid, 0.5 g of toluene sulfonyl acid, and a catalyst amount of methyle hydroquinone were added thereto and then, stirred at 100° C. with a dean-stark reactor under air injection conditions until a theoretical amount was reached. When a reaction was completed, after adding 10 mL of a saturated NaHCO₃ aqueous solution, 100 mL of water, and 200 mL of methylene chloride thereto, neutralization, extraction, moisture removal, and solvent concentration were sequentially performed. A product therefrom was dried for 24 hours, obtaining compound represented by Chemical Formula 4-1.

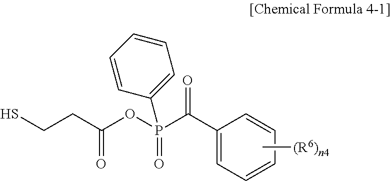

### (Preparation of Curable Compositions)

The curable compositions according to Examples 1 to 18 and Comparative Examples 1 to 4 were prepared based on each of the following components.

### (A) Quantum Dots

(A-1) Surface-modified green quantum dots prepared in Preparation Example 1
(A-2) Surface-modified green quantum dots prepared in Preparation Example 2
(A-3) Surface-modified green quantum dots prepared in Preparation Example 3
(A-4) Surface-modified green quantum dots prepared in Preparation Example 4
(A-5) Surface-modified green quantum dots prepared in Preparation Example 5
(A-6) Surface-modified green quantum dots prepared in Preparation Example 6
(A-7) Surface-modified green quantum dots prepared in Preparation Example 7
(A-8) Surface-modified green quantum dots prepared in Preparation Example 8
(A-9) Surface-modified green quantum dots prepared in Preparation Example 9
(A-10) Surface-modified green quantum dots prepared in Preparation Example 10
(A-11) Surface-modified green quantum dots prepared in Preparation Example 11
(A-12) Surface-modified green quantum dots prepared in Preparation Example 12
(A-13) Surface-modified green quantum dots prepared in Preparation Example 13
(A-14) Surface-modified green quantum dots prepared in Preparation Example 14
(A-15) Surface-modified green quantum dots prepared in Preparation Example 15
(A-16) Surface-modified green quantum dots prepared in Preparation Example 16
(A-17) Surface-modified green quantum dots prepared in Preparation Example 17
(A-18) Surface-modified green quantum dots prepared in Preparation Example 18
(A-19) Surface-modified green quantum dots prepared in Comparative Preparation Example 1
(A-20) Surface-modified green quantum dots prepared in Comparative Preparation Example 2
(A-21) Surface-modified green quantum dots prepared in Comparative Preparation Example 3
(A-22) Surface-modified green quantum dots prepared in Comparative Preparation Example 4

### (B) Polymerizable Compound

Compound represented by Chemical Formula 6-2 (M200, Miwon Chemical)

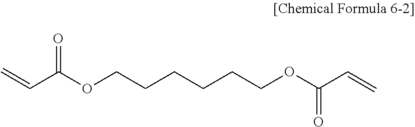 [SMILES: C=CC(=O)OCCCCCCOC(=O)C=C]

### (C) Photopolymerization Initiator

TPO-L (Polynetron)

### (D) Light Diffusing Agent

Titanium dioxide dispersion (rutile type TiO₂; D50 (180 nm), solid content 50 wt %, Iridos Co., Ltd.)

### (E) Polymerization Inhibitor

Methyl hydroquinone (TOKYO CHEMICAL)

### Examples 1 to 18 and Comparative Examples 1 to 4

Specifically, the surface-modified green quantum dots and the polymerizable compound were mixed and stirred for 12 hours. Herein, a polymerization inhibitor was added thereto and then, stirred for 5 minutes. Then, if necessary, a photoinitiator was added, and then a light diffusing agent was added.

(Taking Example 1 as an example, 41 g of the surface-modified green quantum dots and 41 g of a compound represented by Chemical Formula 6-2 as the polymerizable compound were mixed and stirred to prepare green quantum dot dispersion, 10.95 g of another polymerizable compound represented by Chemical Formula 6-2 and 0.05 g of the polymerization inhibitor were added thereto and then, stirred for 5 minutes, and subsequently, 3 g of the photoinitiator and 4 g of the light diffusing agent were added thereto and then, stirred, preparing a curable composition (ink).)

Specific compositions are shown in Tables 2 and 3.

TABLE 2
(unit: wt %)

| | | | | | | | | | | | | | Polym- | Polym- | | Light |
|---|---|---|---|---|---|---|---|---|---|---|---|---|---|---|---|---|
| | Quantum dot | | | | | | | | | | | | erizable | erization | Photo- | diffusing |
| | (A-1) | (A-2) | (A-3) | (A-4) | (A-5) | (A-6) | (A-7) | (A-8) | (A-9) | (A-10) | (A-11) | (A-12) | compound | inhibitor | initiator | agent |
| Ex. 1 | 41 | — | — | — | — | — | — | — | — | — | — | — | 51.95 | 0.05 | 3 | 4 |
| Ex. 2 | — | 41 | — | — | — | — | — | — | — | — | — | — | 51.95 | 0.5 | 3 | 4 |
| Ex. 3 | — | — | 41 | — | — | — | — | — | — | — | — | — | 54.95 | 0.5 | — | 4 |
| Ex. 4 | — | — | — | 41 | — | — | — | — | — | — | — | — | 54.95 | 0.5 | — | 4 |
| Ex. 5 | — | — | — | — | 41 | — | — | — | — | — | — | — | 54.95 | 0.5 | — | 4 |
| Ex. 6 | — | — | — | — | — | 41 | — | — | — | — | — | — | 51.95 | 0.5 | 3 | 4 |
| Ex. 7 | — | — | — | — | — | — | 41 | — | — | — | — | — | 51.95 | 0.5 | 3 | 4 |
| Ex. 8 | — | — | — | — | — | — | — | 41 | — | — | — | — | 54.95 | 0.5 | — | 4 |
| Ex. 9 | — | — | — | — | — | — | — | — | 41 | — | — | — | 54.95 | 0.5 | — | 4 |
| Ex. 10 | — | — | — | — | — | — | — | — | — | 41 | — | — | 54.95 | 0.5 | — | 4 |
| Ex. 11 | — | — | — | — | — | — | — | — | — | — | 41 | — | 51.95 | 0.5 | 3 | 4 |
| Ex. 12 | — | — | — | — | — | — | — | — | — | — | — | 41 | 54.95 | 0.5 | — | 4 |

TABLE 3
(unit: wt %)

| | | | | | | | | | | | Polym- | Polym- | | Light |
|---|---|---|---|---|---|---|---|---|---|---|---|---|---|---|
| | Quantum dot | | | | | | | | | | erizable | erization | Photo | diffusing |
| | (A-13) | (A-14) | (A-15) | (A-16) | (A-17) | (A-18) | (A-19) | (A-20) | (A-21) | (A-22) | compound | inhibitor | initiator | agent |
| Ex. 13 | 41 | — | — | — | — | — | — | — | — | — | 54.95 | 0.05 | — | 4 |
| Ex. 14 | — | 41 | — | — | — | — | — | — | — | — | 54.95 | 0.05 | — | 4 |
| Ex. 15 | — | — | 41 | — | — | — | — | — | — | — | 51.95 | 0.05 | 3 | 4 |
| Ex. 16 | — | — | — | 41 | — | — | — | — | — | — | 54.95 | 0.05 | — | 4 |
| Ex. 17 | — | — | — | — | 41 | — | — | — | — | — | 54.95 | 0.05 | — | 4 |
| Ex. 18 | — | — | — | — | — | 41 | — | — | — | — | 54.95 | 0.05 | — | 4 |
| Comp. | — | — | — | — | — | — | 41 | — | — | — | 51.95 | 0.05 | 3 | 4 |
| Ex. 1 | | | | | | | | | | | | | | |
| Comp. | — | — | — | — | — | — | — | 41 | — | — | 51.95 | 0.05 | 3 | 4 |
| Ex. 2 | | | | | | | | | | | | | | |
| Comp. | — | — | — | — | — | — | — | — | 41 | — | 51.95 | 0.05 | 3 | 4 |
| Ex. 3 | | | | | | | | | | | | | | |
| Comp. | — | — | — | — | — | — | — | — | — | 41 | 51.95 | 0.05 | 3 | 4 |
| Ex. 4 | | | | | | | | | | | | | | |

### Evaluation: Evaluation of Viscosity, Light Efficiency, Thermal Process Maintenance Rate, Out-Gas, Curing Rate of Curable Compositions

Each curable composition according to Examples 1 to 18 and Comparative Examples 1 to 4 were evaluated with respect to viscosity, light efficiency, thermal process retention, out-gas characteristics, and a curing rate, and the results are shown in Table 4.

### (Evaluation of Viscosity)

A viscometer (RV-2 spins, 23 rpm, DV-H, Brookfield Engineering Laboratories, Inc.) was used to measure the viscosity at 25° C.

### (Evaluation of Light Efficiency)

2 mL of each curable composition was spin-coated on a glass substrate at 1,500 rpm and exposed at 5 J for 9 seconds in a nitrogen UV exposer to form QD films, and the QD films were measured with respect to an initial blue light conversion rate by using a light efficiency meter (QE-2100, Otsuka Electronics Co., Ltd.).

### (Evaluation of Thermal Process Maintenance Rate)

A substrate on which each of the QD films was formed was baked on a hotplate at 180° C. under a nitrogen atmosphere for 30 minutes and cooled at room temperature (23° C.) for 3 hours. Subsequently, the light efficiency meter was used to remeasure blue light conversion rates of the films, which were used in the following calculation equation to calculate a thermal process maintenance rate (%).

$$Thermal process maintenance rate ( \% ) = [ Light conversion rate ( after baking ) / Initial light conversion rate ] * 100$$

### (Evaluation of Out-gas Characteristics)

2 mL of each curable composition was spin-coated on a glass substrate at 1,500 rpm, preparing three specimens, respectively. Each substrate was exposed in the nitrogen UV exposer, baked in a 180° C. oven for 30 minutes, and cooled at room temperature (23° C.) for 3 hours, preparing QD cured films. Subsequently, five samples with a size of 1 cm×5 cm were taken around the center of each substrate and put in a GC vial, and then, an amount of out-gas was measured under a 180° C. collection condition through a head-space GC analysis.

### (Evaluation of Curing Rate)

An FT-IR spectrometer (Cary 600, Agilnet Technologies) was used to measure C═C bond (1647-1616 cm⁻¹) and C═O bond (1658-1783 cm⁻¹) peak area integral values in each curable composition and also, C═C bond and C═O bond peak area integral values in each QD cured film after baking the curable compositions in the 180° C. oven for 30 minutes and cooling them to room temperature (23° C.) for 3 hours, which were used to calculate a curing rate (%) according to the following calculation equation.

$$Curing rate \text{} ( \% ) =$$

$$[ 1 - ( C = C bond peak area integral value in QD cured film / ( C = O bond peak area integral value in QD cured film ) / ( C = C bond peak area integral value curable composition / ( C = O bond peak area integral value in curable composition ) ] * 100$$

TABLE 4

| | | | Thermal | | |
|---|---|---|---|---|---|
| | | | process | | |
| | | Light | maintenance | Out- | Curing |
| | Viscosity | efficiency | rate | gas | rate |
| | (cps) | (%) | (%) | (%) | (%) |
| Example 1 | 25.1 | 31.3 | 99 | 110 | 91 |
| Example 2 | 25.3 | 31.2 | 99 | 115 | 92.5 |
| Example 3 | 33.3 | 31.5 | 99 | 105 | 93.5 |
| Example 4 | 27.8 | 31.6 | 99 | 106 | 93.3 |
| Example 5 | 26.4 | 31.5 | 99 | 111 | 93.1 |
| Example 6 | 25.2 | 31.9 | 100 | 128 | 91.1 |
| Example 7 | 25.3 | 31.7 | 100 | 131 | 91.5 |
| Example 8 | 30.2 | 31.8 | 100 | 119 | 93.6 |
| Example 9 | 25.9 | 31.9 | 100 | 125 | 92.9 |
| Example 10 | 24.9 | 31.9 | 100 | 119 | 92.8 |
| Example 11 | 24.2 | 32.2 | 100 | 129 | 91.4 |
| Example 12 | 28.9 | 32.1 | 100 | 118 | 93.2 |
| Example 13 | 26.7 | 31.9 | 100 | 123 | 93.3 |
| Example 14 | 24.8 | 32.4 | 100 | 117 | 93.6 |
| Example 15 | 24.0 | 32.5 | 100 | 133 | 91.7 |
| Example 16 | 26.6 | 32.0 | 100 | 126 | 94.6 |
| Example 17 | 25.4 | 32.4 | 100 | 129 | 93.7 |
| Example 18 | 24.2 | 32.5 | 100 | 111 | 93 |
| Comparative | 26.0 | 31.0 | 98 | 100 | 91 |
| Example 1 | | | | | |
| Comparative | 23.8 | 32.0 | 100 | 130 | 92 |
| Example 2 | | | | | |
| Comparative | 24.3 | 31.2 | 100 | 120 | 93 |
| Example 3 | | | | | |
| Comparative | 78.0 | 20.0 | 100 | 100 | 95 |
| Example 4 | | | | | |

Referring to Table 4, the curable compositions according to Examples 1 to 18 were prevented from deterioration of the thermal process maintenance rate and simultaneously exhibited low viscosity, high light efficiency, low out-gas, and a high curing rate, compared with the curable compositions according to Comparative Examples 1 to 4.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

What is claimed is:

1. A curable composition, comprising:
(A) a quantum dot surface-modified with at least two quantum dot surface-modifying materials; and
(B) a polymerizable compound,
wherein the quantum dot surface-modifying materials include a first surface-modifying material represented by Chemical Formula 1 and a second surface-modifying material represented by Chemical Formula 2: 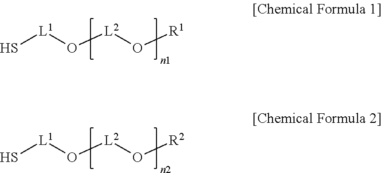
wherein, in Chemical Formula 1 and Chemical Formula 2,
R¹ is a substituted or unsubstituted C6 to C20 aryl group,
R² is a C1 to C20 alkyl group unsubstituted or substituted with a C1 to C10 alkyl group,
L¹ and L² are each independently a substituted or unsubstituted C1 to C20 alkylene group, and
n1 and n2 are each independently an integer from 2 to 20.

2. The curable composition of claim 1, wherein
the first surface-modifying material and the second surface-modifying material are included in a weight ratio of 30:70 to 70:30 based on the total amount of the quantum dot surface-modifying materials.

3. The curable composition of claim 1, wherein
the first surface-modifying material is represented by Chemical Formula 1-1:

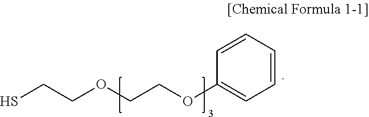

4. The curable composition of claim 1, wherein
the second surface-modifying material is represented by Chemical Formula 2-1:

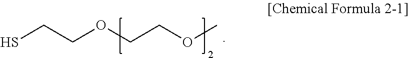

5. The curable composition of claim 1, wherein
the quantum dot is a quantum dot that is further surface-modified with a third surface-modifying material represented by Chemical Formula 3: 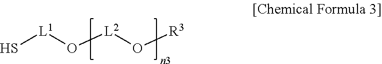
wherein, in Chemical Formula 3,
R³ is a C1 to C20 alkyl group substituted with a vinyl group,
L¹ and L² are each independently a substituted or unsubstituted C1 to C20 alkylene group, and
n3 is an integer from 2 to 20.

6. The curable composition of claim 5, wherein
the third surface-modifying material of the quantum dot surface-modifying materials is included in an amount equal to or less than that of the first surface-modifying material or the second surface-modifying material.

7. The curable composition of claim 5, wherein
the third surface-modifying material is represented by Chemical Formula 3-1:

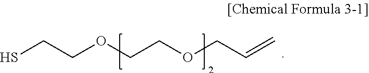

8. The curable composition of claim 5, wherein
the first surface-modifying material and second surface-modifying material are included in an amount of 60 wt % to 90 wt % based on the total amount of the quantum dot surface-modifying materials.

9. The curable composition of claim 5, wherein
the quantum dot is a quantum dot that is further surface-modified with a fourth surface-modifying material represented by Chemical Formula 4: 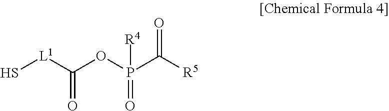
wherein, in Chemical Formula 4,
R⁴ and R⁵ are each independently a substituted or unsubstituted C6 to C20 aryl group, and
L¹ is a substituted or unsubstituted C1 to C20 alkylene group.

10. The curable composition of claim 9, wherein
the fourth surface-modifying material of the quantum dot surface-modifying materials is included in a smaller weight than the third surface-modifying material.

11. The curable composition of claim 9, wherein
the fourth surface-modifying material of the quantum dot surface-modifying materials is included in an amount of 1 wt % to 5 wt % based on the total amount of the quantum dot surface-modifying materials.

12. The curable composition of claim 9, wherein
the fourth surface-modifying material is represented by Chemical Formula 4-1: 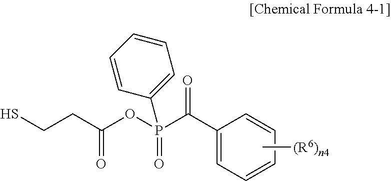
wherein, in Chemical Formula 4-1,
R⁶ is a substituted or unsubstituted C1 to C20 alkyl group, and
n4 is an integer from 1 to 5.

13. The curable composition of claim 9, wherein
based on the total amount of the quantum dot surface-modifying materials,
the first surface-modifying material is included in an amount of 30 wt % to 70 wt %;
the second surface-modifying material is included in an amount of 15 wt % to 50 wt %;
the third surface-modifying material is included in an amount of 10 wt % to 30 wt %; and
the fourth surface-modifying material is included in an amount of 1 wt % to 5 wt %.

14. The curable composition of claim 1, wherein
the curable composition is a solvent-free curable composition.

15. The curable composition of claim 14, wherein
the solvent-free curable composition includes, based on the total amount of the solvent-free curable composition,
5 wt % to 60 wt % of the quantum dot; and
40 wt % to 95 wt % of the polymerizable compound.

16. The curable composition of claim 1, wherein
the curable composition further includes a polymerization initiator, a light diffusing agent, a polymerization inhibitor, or a combination thereof.

17. The curable composition of claim 16, wherein
the light diffusing agent includes barium sulfate, calcium carbonate, titanium dioxide, zirconia, or a combination thereof.

18. The curable composition of claim 1, wherein
the curable composition further includes a solvent.

19. The curable composition of claim 18, wherein
the curable composition includes 1 wt % to 40 wt % of the quantum dot; 1 wt % to 20 wt % of the polymerizable compound; and 40 wt % to 80 wt % of the solvent, based on the total weight of the curable composition.

20. The curable composition of claim 1, wherein
the curable composition further includes malonic acid; 3-amino-1,2-propanediol; a silane-based coupling agent; a leveling agent; a fluorine-based surfactant; or a combination thereof.

21. A cured layer manufactured using the curable composition of any one of claim 1 to claim 20.

22. A color filter comprising the cured layer of claim 21.

23. A display device comprising the color filter of claim 22.
